(19) United States
(12) Patent Application Publication
(10) Pub. No.: US 2023/0360553 A1
(43) Pub. Date: Nov. 9, 2023

(54) METHOD FOR CREATING A MODIFIED FLIGHT SIMULATION PROGRAM FOR A FLIGHT SIMULATION SYSTEM, AND THE FLIGHT SIMULATION SYSTEM EXECUTING THE MODIFIED FLIGHT SIMULATION PROGRAM

(71) Applicant: BROGENT TECHNOLOGIES INC., Kaohsiung (TW)

(72) Inventors: Kuo-Chen Chen, Kaohsiung (TW); Po-Hsiung Chang, Kaohsiung (TW); Ying-Yun Chang, Kaohsiung (TW); Wan-Yu Chung, Kaohsiung (TW); Che-Jen Yeh, Kaohsiung (TW)

(21) Appl. No.: 18/311,395

(22) Filed: May 3, 2023

(30) Foreign Application Priority Data
May 5, 2022 (TW) 111116991

(51) Int. Cl. G09B 9/30; G09B 9/50; G09B 9/12

(52) U.S. Cl. CPC G09B 9/301; G09B 9/50; G09B 9/12

(57) ABSTRACT

A method for creating a modified flight simulation program for a flight simulation system includes: obtaining a demonstration flight record associated with a preset track route of a virtual airplane; generating an add-on content pack for the flight simulation program based on the demonstration flight record; and merging the add-on content pack to the flight simulation program to create a modified flight simulation program. The generation of the add-on content pack includes: mapping the preset track route to geographical coordinate data in the real world, creating a first program module associated with a demonstration mode enabling a demonstration virtual flight along the preset track route, creating a second program module associated with an assisted flight mode enabling user control for a virtual flight within a free-flight space, and creating the add-on content pack that includes the first and the second program modules.

### CROSS-REFERENCE TO RELATED APPLICATION

This application claims priority to Taiwanese Invention Patent Application No. 111116991, filed on May 5, 2022.

### FIELD

The disclosure relates to a method for creating a modified simulation program and a simulation system executing the modified simulation program, and more particularly to a method for creating a modified flight simulation program and a flight simulation system executing the modified flight simulation program.

### BACKGROUND

In the field of aviation, the piloting experience of operating aircrafts may be very attractive to the public. However, a number of barriers, including the availability of the aircrafts, the associated costs, the technical requirements to operate the aircrafts, etc., making the piloting experience less accessible to the public. As such, flight simulation systems, including flight simulation software and flight motion simulator equipment, have been developed to provide flight experience for users without actually using an airplane.

It is noted that while the conventional flight simulation systems are able to make the flight experience more accessible, details of operating the equipment, such as remembering the functions of the controllers included in the equipment, and the order of steps to be performed during various procedures in response to different conditions (e.g., passing a turbulence), etc., may prove difficult to master just as when flying an actual airplane.

### SUMMARY

In order to enable casual users to quickly get the hang of operations of the flight simulation system, the design of the flight simulation system may be improved to improve the accessibility of flight simulation experience. Therefore, an object of the disclosure is to provide a method for creating a modified flight simulation program for a flight simulation system.

According to one embodiment of the disclosure, the method for creating a modified flight simulation program for a flight simulation system is provided. The flight simulation system includes a computer device that stores a flight simulation program therein. The method includes:
obtaining a demonstration flight record that includes a preset track route and a plurality of parameter sets associated with the preset track route of a virtual airplane;
executing a program editor to generate an add-on content pack for the flight simulation program based on the demonstration flight record; and
executing a software development kit (SDK) to merge the add-on content pack to the flight simulation program to create a modified flight simulation program,

Another object of the disclosure is to provide a flight simulation system that executes the modified flight simulation program as described above to be able to provide a virtual flight for a user.

According to one embodiment of the disclosure, the flight simulation system comprising a computer device that is configured to execute the modified flight simulation program as claimed in claim 1, so as to provide the virtual flight that includes the demonstration mode and the assisted flight mode to a user.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 illustrates an exemplary flight simulation system according to one embodiment of the disclosure.

FIG. 2 is a flow chart illustrating steps of a method for creating a modified flight simulation program for a flight simulation system according to one embodiment of the disclosure.

FIG. 3 is a diagram illustrating content stored in a data storage as the method of FIG. 2 is being implemented.

FIG. 4 illustrates a virtual environment being displayed by a display when a modified flight simulation program is executed, and a demonstration mode is selected.

FIG. 5 illustrates the virtual environment being displayed by the display when the modified flight simulation program is executed, and an assisted flight mode is selected.

FIG. 6 is a flow chart illustrating steps of a method for creating a modified flight simulation program for a flight simulation system according to one embodiment of the disclosure.

FIG. 7 illustrates an example showing a plurality of event triggering areas in the form of dots, and contents of some of the associated event data packs being displayed on the display for the user.

FIG. 8 illustrates an exemplary flight simulation system according to one embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

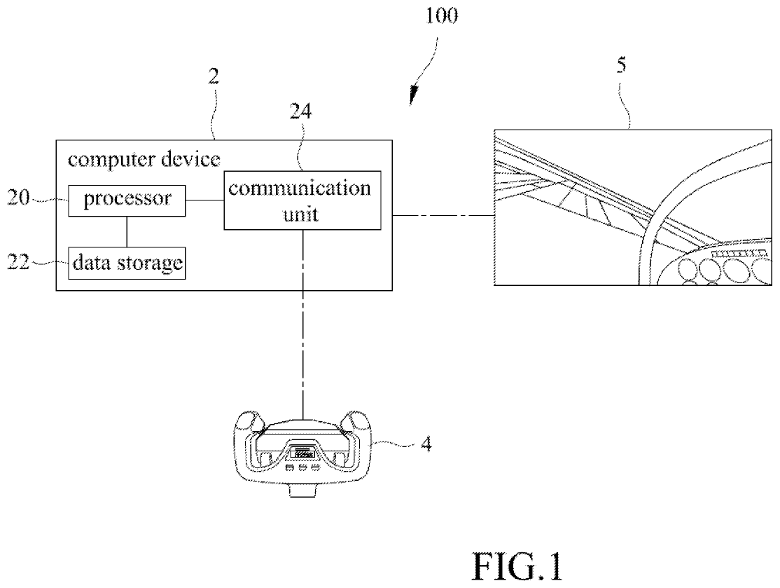

FIG. 1 illustrates an exemplary flight simulation system 100 according to one embodiment of the disclosure. In this embodiment, the flight simulation system 100 includes a computer device 2, a user controller 4, and a display 5.

The computer device 2 may be embodied using a server, a personal computer, a laptop, a tablet, a smartphone, or other devices that are capable of performing computations as described below. The computer device 2 includes a processor 20, a data storage 22 and a communication unit 24.

The data storage 22 is connected to the processor 20, and stores a flight simulation program 30 including instructions that, when executed by the processor 20, cause the processor 20 to perform the operations as described below. In this embodiment, the flight simulation program 30 may be embodied using Microsoft Flight Simulator, but is not limited to such. In addition, the data storage 22 further stores a software development kit (SDK) 31 and a program editor 32. The SDK 31 may be embodied using commercially available SDKs. For example, the SDK 31 may be the Flight Simulator SDK provided by Microsoft. In the case that the flight simulation program 30 is embodied using the Microsoft Flight Simulator, the program editor 32 may be embodied using the project editor, which is provided by a “developer mode” editing function under the SDK 31.

The communication unit 24 enables the computer device 2 to communicate with the user controller 4 and the display 5 via wired or wireless communication.

The user controller 4 may be embodied using hardware components that are built to be similar to various controlling mechanism used for piloting an actual airplane. The user controller 4 enables a user to control a virtual airplane for a virtual flight.

The display 5 may be embodied using a liquid crystal display (LCD) screen, a projector and a screen, or a dome projection screen used for virtual reality (VR) application, so as to simulate experience inside a cockpit. The display 5 is configured to display images received from the computer device 2.

In use, when a user begins a flight simulation, the processor 20 of the computer device 2 executes the flight simulation program 30. In response, the processor 20 continuously generates a number of environmental images that constitute a virtual environment, and transmits the environmental images to the display 5 for presenting the virtual environment to the user. Simultaneously, the user holds the user controller 4 and is able to operate the user controller 4 to input control signals, that is, to “pilot” a virtual airplane within the virtual environment.

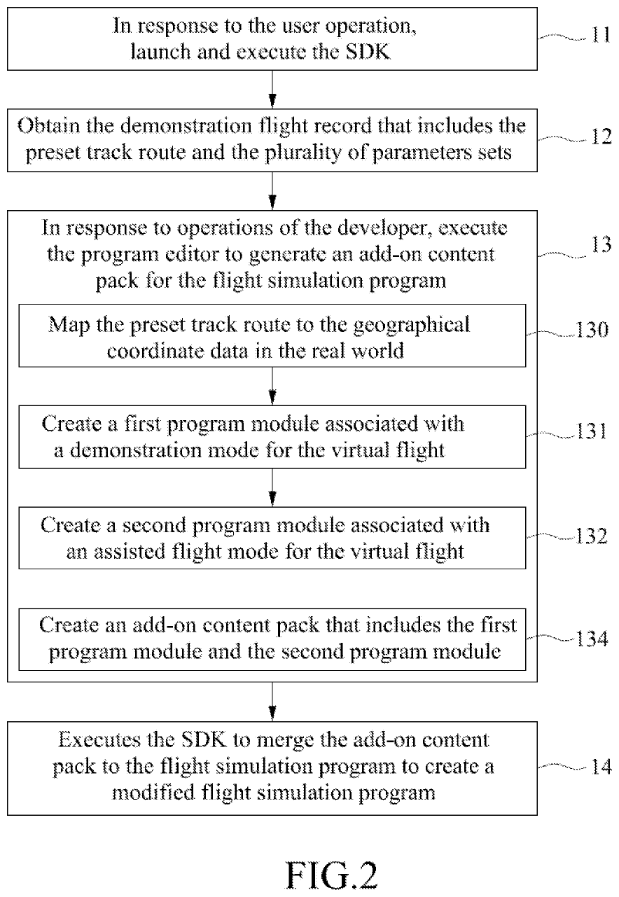

FIG. 2 is a flow chart illustrating steps of a method for creating a modified flight simulation program for a flight simulation system according to one embodiment of the disclosure. In this embodiment, the method is implemented using the flight simulation system 100 as shown in FIG. 1.

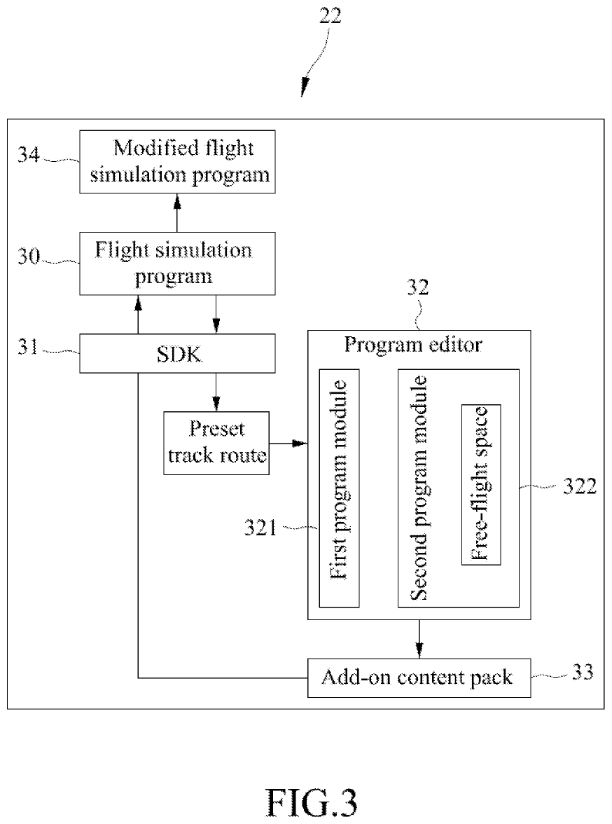

FIG. 3 is a diagram illustrating the content stored in the data storage 22 as the method of FIG. 2 is being implemented. In the beginning, the developer operates the computer device 2 to execute the SDK 31. Specifically, the developer may operate an interface of the computer device 2 (e.g., a keyboard and a mouse, a touchscreen, etc. that are not depicted in the drawings) to execute the SDK 31. Accordingly, in step 11, the computer device 2, in response to the user operation, launches and executes the SDK 31.

Then, the developer operates the flight simulation system 100 to obtain a demonstration flight record. In embodiments, the demonstration flight record includes a preset track route and a plurality of parameter sets associated with the preset track route. As a result, in step 12, the computer device 2 executing the flight simulation program 30 obtains the demonstration flight record that includes the preset track route and the plurality of parameters sets. The preset track route may be represented in the form of a plurality of sets of coordinates in a three-dimensional (3D) coordinate system associated with the virtual environment. In this embodiment, the demonstration flight record may be obtained by the developer operating the user controller 4 to actually pilot a virtual airplane to perform a virtual flight using the flight simulation system 100 that executes the flight simulation program 30. The virtual flight includes a liftoff sequence, a flight sequence, and a landing sequence. As such, the preset track route may include the liftoff segment associated with a track of the virtual airplane during the liftoff sequence, the flight segment associated with a track of the virtual airplane during the flight sequence, and the landing segment associated with a track of the virtual airplane during the landing sequence.

Then, in step 13, the computer device 2, in response to operations of the developer, executes the program editor 32 to generate an add-on content pack 33 for the flight simulation program 30 based on the demonstration flight record.

In this embodiment, step 13 includes a number of sub-steps. Specifically, referring to FIG. 2, in sub-step 130, the computer device 2 executes a program that contains real world geographical coordinate data (e.g., Google Earth), and maps the preset track route to the geographical coordinate data in the real world. It is noted that the virtual environment may be constructed to simulate a real world location (e.g., above a city).

In sub-step 131, the computer device 2 executes the program editor 32 to create a first program module 321 associated with a demonstration mode for the virtual flight provided by the flight simulation program 30.

The demonstration mode is designed to enable a user to experience a demonstration virtual flight along the preset track route, in which user control is disabled. During the demonstration virtual flight, the plurality of parameter sets included in the demonstration flight record are loaded and applied to the flight simulation program 30, and the user is not required to do anything to experience the demonstration virtual flight.

In sub-step 132, the computer device 2 executes the program editor 32 to create a second program module 322 associated with an assisted flight mode for the virtual flight provided by the flight simulation program 30.

Specifically, in this embodiment, user operation of the user controller 4 to pilot the virtual airplane is enabled, and the second program module 322 includes instructions that enable the processor 20 to, when it is determined that some predetermined incidents occurred during the virtual flight, temporarily disable the user control and take over the control of the virtual airplane.

In embodiments, to create the second program module 322, the computer device 2 may further define a free-flight space. Specifically, the free-flight space may be bounded by a plurality of sets of 3D coordinates associated with the geographical coordinate data. For example, the free-flight space may be defined as a space surrounding the flight segment of the preset track route, such as space within a predetermined distance from the flight segment of the preset track route (e.g., 300 meters). That is, when the virtual airplane diverges from the preset track route farther than the predetermined distance, the processor 20 may determine that the virtual airplane has moved out of the free-flight space, and may automatically disable user control, and take over the control of the virtual airplane to move the virtual airplane back to the preset track route (i.e., move back in the free-flight space) before enabling user control again.

In other cases, the free-flight space may also be defined by a height floor during the flight sequence. For example, typically, when an airplane is flying below a height of 500 meters, it may be determined that conditions for a “stall” is very likely to occur for inexperienced pilots, which may cause the user to lose control of the virtual airplane. As such, the height floor may be set at 530 meters.

In sub-step 134, the developer executes the program editor 32 to create an add-on content pack 33 that includes the first program module 321 and the second program module 322. In creating the add-on content pack 33, a function for allowing the user to switch between the demonstration mode and the assisted flight mode during the virtual flight may also be added.

After the add-on content pack 33 is created, in step 14, the computer device 2 executes the SDK 31 to merge the add-on content pack 33 to the flight simulation program 30 to create a modified flight simulation program 34.

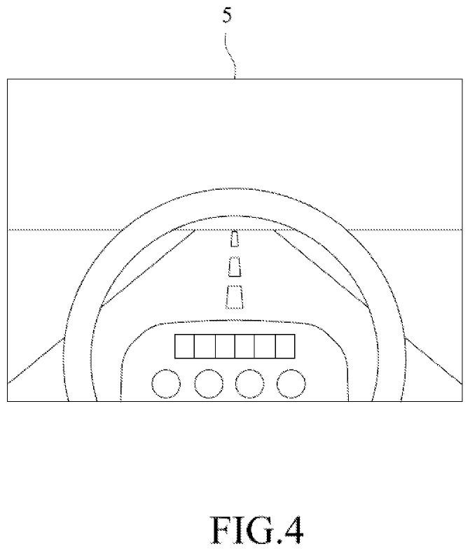

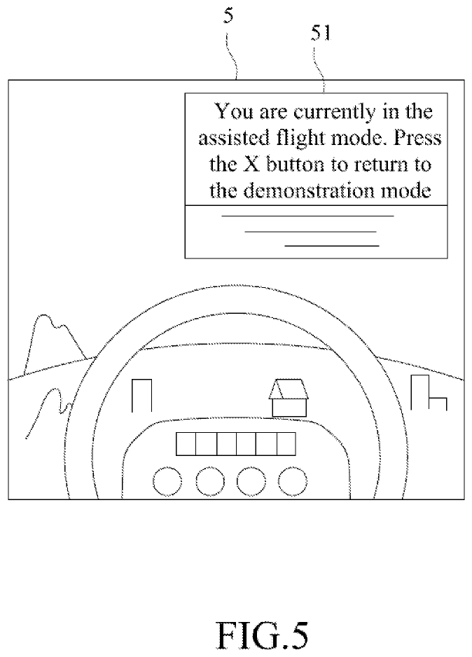

FIG. 4 illustrates the virtual environment being displayed by the display 5 when the modified flight simulation program 34 is executed, and the demonstration mode is selected. Specifically, FIG. 4 illustrates the virtual airplane being in the liftoff sequence. FIG. 5 illustrates the virtual environment being displayed by the display 5 when the modified flight simulation program 34 is executed, and the assisted flight mode is selected.

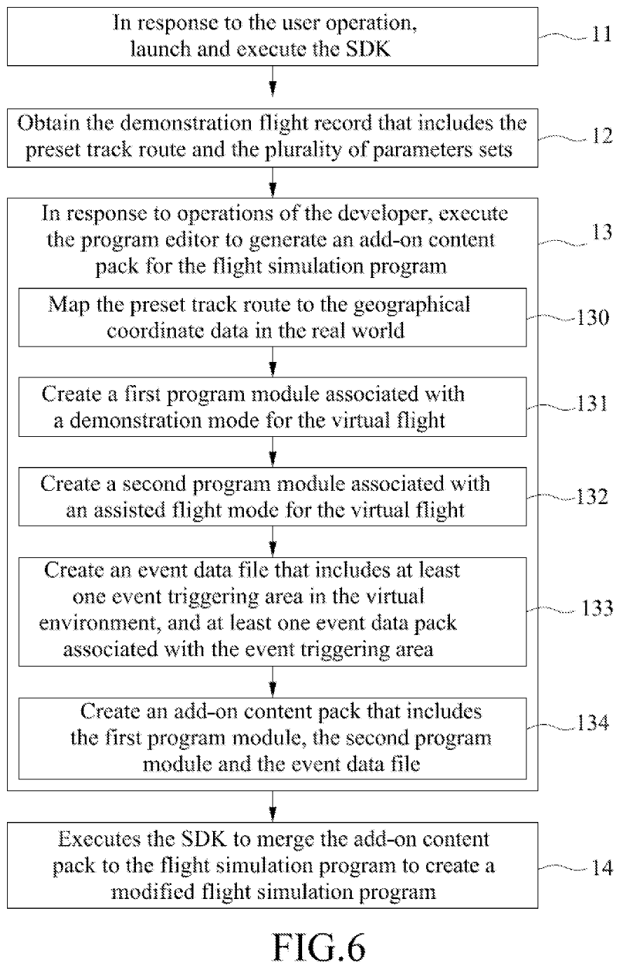

FIG. 6 is a flow chart illustrating steps of a method for creating a modified flight simulation program according to one embodiment of the disclosure. In this embodiment, the method is implemented using the flight simulation system 100 as shown in FIG. 1.

This embodiment differs from the embodiment of FIG. 2 in the detailed operation of step 13. Specifically, step 13 further includes a sub-step 133, between sub-steps 132 and 134. In sub-step 133, the computer device 2 executes the program editor 32 to create an event data file that includes at least one event triggering area in the virtual environment, and at least one event data pack containing information associated with the event triggering area. The event data pack may include content associated with the event triggering area, (e.g., tourist information for landmarks, advertisements for department stores), and includes a multimedia file including texts, an audio component or a video component.

Afterward, in step 134, the computer device 2 executes the program editor 32 to create an add-on content pack 33 that includes the first program module 321, the second program module 322 and the event data file. The add-on content pack 33 is then used to generate the modified flight simulation program 34 in step 14.

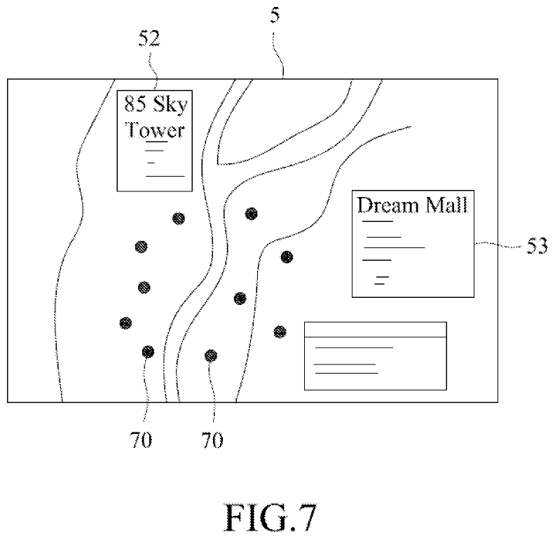

FIG. 7 illustrates an example showing a plurality of event triggering areas 70 (shown in the form of dots), and contents of some of the associated event data packs being displayed on the display 5 for the user according to one embodiment of the disclosure. In this embodiment, the virtual environment is modeled on a part of Kaohsiung City, and the preset track route may be one that starts from the Kaohsiung Main Station to the Cijin District. As the virtual airplane moves along the preset track route during the flight sequence, the virtual airplane may come close to the event triggering area indicating the “85 Sky Tower” building. As such, the processor 20 may present the content of the associated event data pack. In this embodiment, the texts containing the introduction of the 85 Sky Tower may be provided in a window 52 superposing the environmental images and presented to the user, and an audio file that includes a recorded reading of the introduction may be played using a speaker (not depicted in the drawings).

In another segment of the preset track route, the virtual airplane may come close to the event triggering area indicating the “Dream Mall” building. As such, the processor 20 may present the content of the associated event data pack. In this embodiment, the texts containing advertisements from merchants in the Dream Mall may be provided in a window 53 superposing the environmental images and presented to the user.

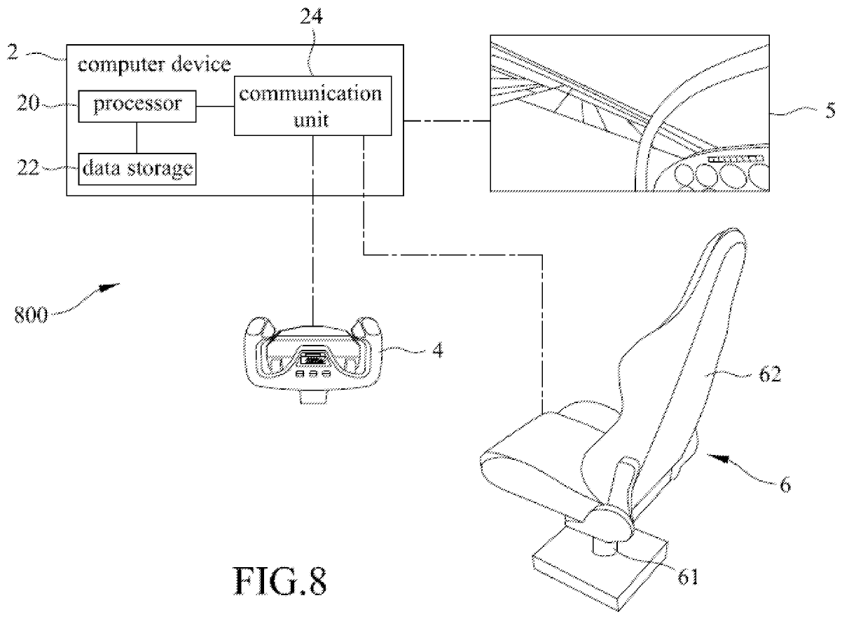

FIG. 8 illustrates an exemplary flight simulation system 800 according to one embodiment of the disclosure. In this embodiment, the flight simulation system 800 includes a computer device 2, a user controller 4, a display 5, and a seating platform 6. The seating platform 6 may include a motor base 61 and a seat 62 disposed on the motor base 61. In use, when the virtual flight is to be experienced, the user may sit on the seat 62, and when the virtual airplane moves, tilts or turns, the processor 20 may transmit a corresponding control signal to the motor base 61 according to the movement of the virtual airplane, which then drives the seat 62 to move accordingly.

To sum up, embodiments of the disclosure provide a method for creating a modified flight simulation program, and a flight simulation system executing the modified flight simulation program. In the method, an add-on content pack that includes program modules to realize a demonstration mode and an assisted flight mode for a virtual flight is created, and attached to a flight simulation program, so as to create the modified flight simulation program. Using the modified flight simulation system, the user may freely choose from the demonstration mode, in which the virtual airplane is automatically piloted along a preset track route, and the assisted flight mode, in which the user is able to operate the controller unit to pilot the virtual airplane within a free-flight space, during the course of the virtual flight.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for creating a modified flight simulation program for a flight simulation system, the flight simulation system comprising a computer device that stores a flight simulation program therein, the method comprising steps of:
obtaining a demonstration flight record that comprises a preset track route and a plurality of parameter sets associated with the preset track route of a virtual airplane;
executing a program editor to generate an add-on content pack for the flight simulation program based on the demonstration flight record; and
executing a software development kit (SDK) to merge the add-on content pack to the flight simulation program to create a modified flight simulation program,
wherein obtaining the demonstration flight record comprises:
performing a virtual flight with the virtual airplane using the flight simulation system that executes the flight simulation program,
controlling the SDK to periodically record locations of the virtual airplane, and to periodically collect the plurality of parameter sets, and
compiling the locations of the virtual airplane and the plurality of parameter sets to form the demonstration flight record, the locations of the virtual airplane serving as the preset track route,
wherein generating the add-on content pack comprises:
executing a program that contains geographical coordinate data in the real world, and mapping the preset track route to the geographical coordinate data in the real world,
creating a first program module associated with a demonstration mode for the virtual flight related to the demonstration flight record, the demonstration mode enabling a user to experience a demonstration virtual flight along the preset track route, in which user control is disabled,
creating a second program module associated with an assisted flight mode for the virtual flight, the assisted flight mode enabling user control for another virtual flight within a free-flight space, and
create an add-on content pack that comprises the first program module and the second program module.

2. The method as claimed in claim 1, wherein the free-flight space is bounded by a plurality of sets of 3D coordinate associated with the geographical coordinate data.

3. The method as claimed in claim 2, wherein the second program module is created to include instructions that enable the computer device to:
when it is determined that the virtual airplane has moved out of the free-flight space, automatically disable user control and take over the control of the virtual airplane to move the virtual airplane back in the free-flight space before enabling the user control again.

4. The method as claimed in claim 1, wherein the second program module is created to include instructions that enable the computer device to:
when it is determined that the virtual airplane has moved out of the free-flight space, automatically disable user control and take over the control of the virtual airplane to move the virtual airplane back in the free-flight space before enabling the user control again.

5. The method as claimed in claim 1, wherein:
the preset track route comprises a liftoff segment associated with a track of the virtual airplane during a liftoff sequence, a flight segment associated with a track of the virtual airplane during a flight sequence, and a landing segment associated with a track of the virtual airplane during a landing sequence; and
the free-flight space is defined with respect to the flight segment of the preset track route.

6. The method as claimed in claim 1, wherein:
the generating of the add-on content pack further comprises creating an event data file that comprises at least one event triggering area in the virtual environment, and at least one event data pack containing information associated with the event triggering area;
the add-on content pack is created to include the first program module, the second program module and the event data file; and
the modified flight simulation program further comprises the function of, when it is determined that the virtual airplane moves in proximity to the event triggering area, triggering an event that comprises presenting the information contained in the event data pack.

7. The method as claimed in claim 6, wherein the event data pack is in the form of a multimedia file comprising texts, an audio component or a video component.

8. A flight simulation system comprising a computer device that is configured to execute the modified flight simulation program as claimed in claim 1, so as to provide the demonstration mode and the assisted flight mode for the virtue flight to a user.

9. The flight simulation system as claimed in claim 8, further comprising a user controller and a display that are connected to the computer device, the user controller enabling the user to control the virtual airplane for the virtual flight, the display being configured to display images received from the computer device.

10. The flight simulation system as claimed in claim 9, further comprising a seating platform that comprises a motor base, and a seat disposed on the motor base,
wherein the motor base is connected to the computer device, and is controlled to drive the seat to move; and
a movement of the seat is controlled by a control signal transmitted from the processor executing the modified flight simulation program.

11. The flight simulation system as claimed in claim 9, further comprising a seating platform that comprises a motor base, and a seat disposed on the motor base,
wherein the motor base is connected to the computer device, and is controlled to drive the seat to move; and
a movement of the seat is controlled by a control signal transmitted from the processor executing the modified flight simulation program.
